(19) United States
(12) Patent Application Publication
(10) Pub. No.: US 2007/0152764 A1
(43) Pub. Date: Jul. 5, 2007

(54) DELAY UNIT OF VOLTAGE CONTROL OSCILLATOR

(75) Inventor: Hsiao-Chyi Lin, Taipei (TW)

Correspondence Address: KIRTON AND MCCONKIE, 60 EAST SOUTH TEMPLE,, SUITE 1800, SALT LAKE CITY, UT, 84111, US

(73) Assignee: VIA TECHNOLOGIES, INC., Taipei (TW)

(21) Appl. No.: 11/564,439

(22) Filed: Nov. 29, 2006

(30) Foreign Application Priority Data
Jan. 3, 2006 (TW) 095100226

(51) Int. Cl. H03K 3/03

(52) U.S. Cl. 331/57

(57) ABSTRACT

A delay unit having a complementary architecture for use in a voltage control oscillator includes a first voltage control oscillating circuit and a second voltage control oscillating circuit. The first voltage control oscillating circuit includes a first gain circuit, a first current-source circuit coupled to the first gain circuit, and a first load circuit. The second voltage control oscillator circuit includes a second gain circuit, a second current-source circuit coupled to the second gain circuit, and a second load circuit. At least one pair of the first and second gain circuits, the first and second current-source circuits and the first and second load circuits are implemented with complementary integrated circuits.

### FIELD OF THE INVENTION

The present invention relates to a delay unit of a voltage control oscillator, and more particularly to a delay unit of a voltage control oscillator having a complementary architecture.

### BACKGROUND OF THE INVENTION

Due to the fast progressing of technology and the needs for human life, technical products such as computer systems and their peripherals and communication products have been developed faster and faster. Among the elements constituting a technical product, a voltage control oscillator plays an important role for providing a clock signal that is essential to modern digital circuits and communication systems. The most popular use of a voltage control oscillator is used in a phase-locked loop (PLL) circuit, e.g. a clock generator or a frequency synthesizer.

Currently, voltage control oscillators include inductor-capacitor oscillators (LC tank), ring oscillators, etc. FIG. 1 schematically shows one kind of conventional ring oscillators, a three-stage ring oscillator. The three-stage ring oscillator 10 includes three serially and cyclically connected delay units 12, 14 and 16. Each of the delay units includes two input terminals and two output terminals, i.e. a positive input terminal IP, a negative input terminal IN, a positive output terminal OP, and a negative output terminal ON. The positive output terminals OP and the negative output terminals ON of the delay units 12 and 14 are respectively connected to the negative input terminals IN and the positive input terminals IP of the delay units 14 and 16, while the positive output terminal OP and the negative output terminal ON of the delay units 16 are respectively connected to the negative input terminal IN and the positive input terminal IP of the delay unit 12.

FIG. 2 is a circuit diagram of a conventional delay unit applicable to the ring oscillator of FIG. 1. The delay unit includes a gain circuit 20, a load circuit 25 and a current-source circuit 27. The gain circuit 20 includes two NMOS transistors 203 and 206. The source electrodes of the two NMOS transistors 203 and 206 are both coupled to ground. The load circuit 25 includes two PMOS transistors 253 and 256. The gate electrodes of the two PMOS transistors 253 and 256 are coupled to the drain electrodes of each other to form cross-coupled load. The drain electrodes of the two PMOS transistors 253 and 256 are further coupled to the drain electrodes of the two NMOS transistors 203 and 206, respectively. The source electrodes of the two PMOS transistors 253 and 256 are both coupled to a voltage source Vcc. The current-source circuit 27 includes two PMOS transistors 273 and 276. The drain electrodes of the two PMOS transistors 273 and 276 are coupled to the drain electrodes of the two PMOS transistors 253 and 256, respectively. The source electrodes of the two PMOS transistors 273 and 276 are both coupled to a voltage source Vcc. Moreover, the gate electrodes of the two PMOS transistors 273 and 276 are coupled to a control voltage Vc so as to control the current-source circuit 27 to generate currents.

Principally, when there is no need for an oscillator to generate clock signals, the oscillator is supposed to be disabled considering power consumption. However, the ring oscillator constructed by serially and cyclically connected delay units shown in FIG. 2 cannot be disabled even if the current-source circuit 27 is turned off to stop supplying current. Instead, the oscillator can only be disabled by cutting off the connection between delay units. This would limit the application of the oscillator.

Another delay unit applicable to the oscillator of FIG. 1 is shown in FIG. 3. The delay unit includes a control circuit 28 inserted between the gain circuit 20 and the cross-coupled load circuit 25 to control the strength of the cross-coupled load circuit 25. The drain electrodes of the two NMOS transistors 283 and 286 included in the control circuit 28 are coupled to the gate electrodes of the two PMOS transistors 256 and 253, respectively, while the source electrodes of the two NMOS transistors 283 and 286 are coupled to the drain electrodes of the two NMOS transistors 203 and 206, respectively. As such, the oscillator constructed by the serially and cyclically connected delay units is capable of being disabled by turning off the delay unit with the control voltage Vc so as to save power. However, the delay unit as shown in FIG. 3 has an inherent body effect problem, which may lower the gain, operable range and operable frequency.

FIG. 4 shows still another delay circuit applicable to the oscillator of FIG. 1. The delay circuit includes a current-source circuit 29 inserted between the gain circuit 20 and ground. As such, it is capable of turning off the oscillator by operating the control voltage V_{C} to stop the current output of the two NMOS transistors 293 and 296. Furthermore, there are two invertors 208 and 209 connected to the two NMOS transistors 203 and 206 of the gain circuit 20, respectively, for enhancing gain. However, as shown in FIG. 4, the disposition of PMOS and NMOS transistors are not balanced in each side of the delay unit, and this would result in an uneven waveform of the clock signal generated by the oscillator. An uneven waveform means that the duty cycle of the clock signal would not be desirably 50%.

Therefore, it is desirable to develop an improved delay unit with flexible applicability, reduced body effect and even waveform of the resulting clock signal.

### SUMMARY OF THE INVENTION

In an embodiment of the present invention, a delay unit for use in a voltage control oscillator includes a first voltage control oscillating circuit and a second voltage control oscillating circuit. The first voltage control oscillating circuit includes a first gain circuit having a first input end, a second input end, a first output end and a second output end; a first current-source circuit coupled to the first gain circuit, and a first load circuit coupled to the first output end and the second output end. The second voltage control oscillator circuit includes a second gain circuit having a third input end, a fourth input end, a third output end and a fourth output end, the third input end, the fourth input end, the third output end and the fourth output end being coupled to the first input end, the second input end, the first output end and the second output end, respectively; a second current-source circuit coupled to the second gain circuit; and a second load circuit coupled to the third output end and the fourth output end. At least one pair of the first and second gain circuits, the first and second current-source circuits and the first and second load circuits are implemented with complementary integrated circuits.

In another embodiment of the present invention, a delay unit for use in a voltage control oscillator includes a NMOS voltage control oscillating circuit and a PMOS voltage control oscillating circuit. The NMOS voltage control oscillating circuit has a first input end, a second input end, a first output end and a second output end. The PMOS voltage control oscillating circuit has a third input end coupled to the first input end, a fourth input end coupled to the second input end, a third output end coupled to the first output end, and a fourth output end coupled to the second output end.

In a further embodiment of the present invention, a delay unit for use in a voltage control oscillator includes a first voltage control oscillating circuit and a second voltage control oscillating circuit coupled to and complementary to each other.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a functional block diagram schematically showing a conventional three-stage ring oscillator;

FIG. 2 is a circuit diagram of a conventional delay unit;

FIG. 3 is a circuit diagram of another conventional delay unit;

FIG. 4 is a circuit diagram of still another conventional delay unit;

FIG. 5 is a circuit diagram of an embodiment of a delay unit according to the invention;

FIG. 6 is a circuit diagram of a delay unit implemented with a NMOS voltage control oscillating circuit;

FIG. 7 is a circuit diagram of a delay unit implemented with a PMOS voltage control oscillating circuit;

FIG. 8 is a circuit diagram of a delay unit implemented with a complementary voltage control oscillating circuit according to the invention;

FIG. 9A is a waveform diagram of a clock signal generated by a four-stage ring voltage control oscillator implemented with the NMOS-based delay unit of FIG. 6;

FIG. 9B is a waveform diagram of a clock signal generated by a four-stage ring voltage control oscillator implemented with the PMOS-based delay unit of FIG. 7;

FIG. 9C is a waveform diagram of a clock signal generated by a four-stage ring voltage control oscillator implemented with the delay unit of FIG. 8 with a complementary architecture;

FIG. 10 is a frequency vs. voltage plot of a voltage control oscillator according to an embodiment of the present invention, which is obtained as a result of corner simulation;

FIG. 11A is a circuit diagram of a first alternative load circuit adapted to be used in the delay unit of FIG. 5;

FIG. 11B is a circuit diagram of a second alternative load circuit adapted to be used in the delay unit of FIG. 5;

FIG. 11C is a circuit diagram of a third alternative load circuit adapted to be used in the delay unit of FIG. 5;

FIG. 11D is a circuit diagram of a fourth alternative load circuit adapted to be used in the delay unit of FIG. 5;

FIG. 12A is a circuit diagram of a mirror circuit of a single ended type voltage control oscillator where the delay unit according to the invention can be applied; and

FIG. 12B is a circuit diagram of an alternative mirror circuit of a single ended type voltage control oscillator where the delay unit according to the invention can be applied.

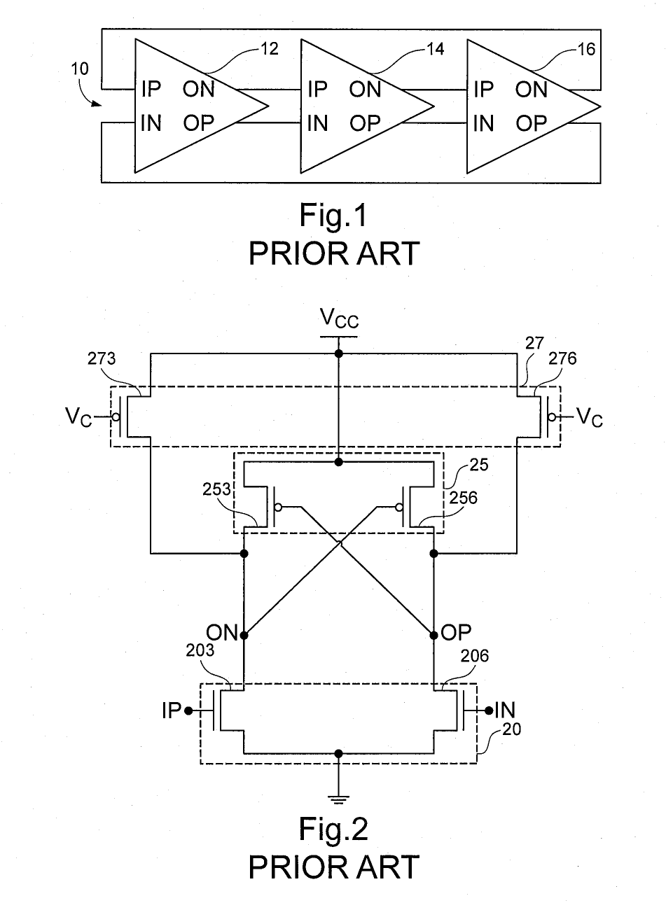

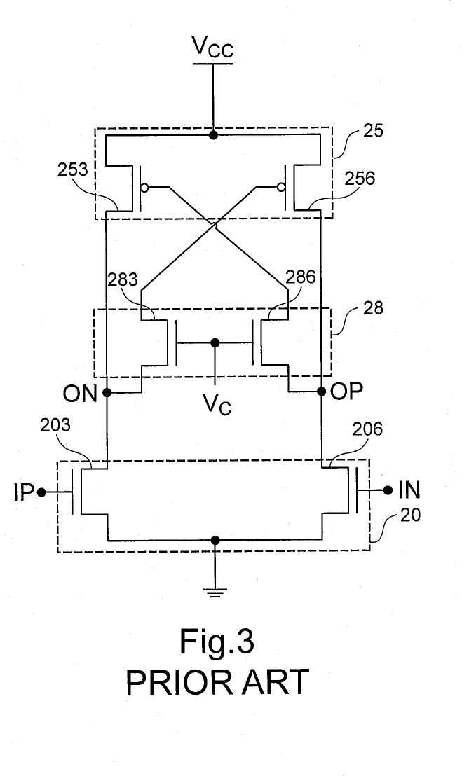

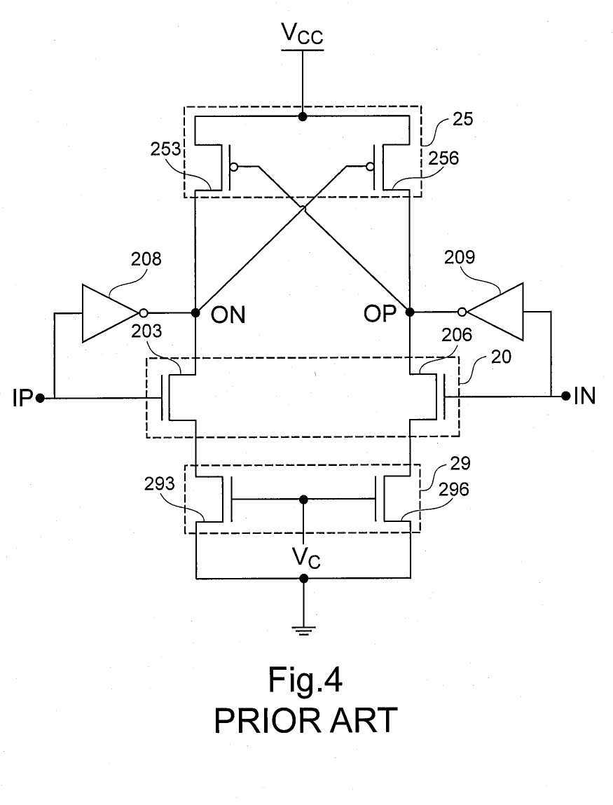

### DETAILED DESCRIPTION OF PREFERRED EMBODIMENTS

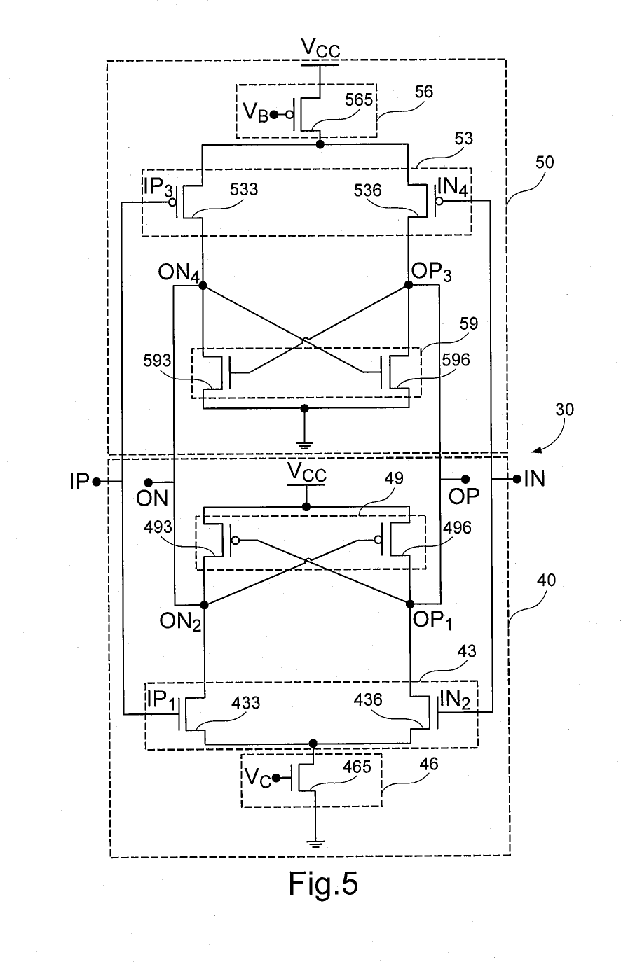

The delay unit according to the present invention has a complementary architecture. In an embodiment illustrated in FIG. 5, the delay unit 30 includes an NMOS voltage control oscillating circuit 40 and a PMOS voltage control oscillating circuit 50 coupled to each other. The NMOS voltage control oscillating circuit 40 includes a first gain circuit 43, a first current-source circuit 46 and a first load circuit 49. The first gain circuit 43 includes a first NMOS transistor 433 and a second NMOS transistor 436. The gate electrodes of the first and second NMOS transistors 433 and 436 serve as input ends IP₁ and IN₂, and the drain electrodes of the first and second NMOS transistors 433 and 436 serve as output ends ON₂ and OP₁. Both the source electrodes of the two NMOS transistors 433 and 436 are coupled to the first current-source circuit 46.

The first current-source circuit 46 includes a third NMOS transistor 465. The drain electrode of the third NMOS transistor 465 is coupled to the source electrodes of the two NMOS transistors 433 and 436, while its source electrode is coupled to ground and its gate electrode is coupled to a first control voltage V_{C}. With the first control voltage V_{C}, the current output from the drain electrode of the third NMOS transistor 465 to the two NMOS transistors 433 and 436 is controlled. The first load circuit 49 is a cross-coupled load circuit which includes a fourth PMOS transistor 493 and a fifth PMOS transistor 496. The drain electrodes of the two PMOS transistors 493 and 496 are respectively coupled to the output ends ON₂ and OP₁ of the NMOS transistors 433 and 436 of the first gain circuit 43, and in addition, coupled to the gate electrodes of each other. Furthermore, both the source electrodes of the two PMOS transistors 493 and 496 are coupled to a voltage source V_{CC}.

The PMOS voltage control oscillating circuit 50 includes a second gain circuit 53, a second current-source circuit 56 and a second load circuit 59. The second gain circuit 53 includes a first PMOS transistor 533 and a second PMOS transistor 536. The gate electrodes of the two PMOS transistors 533 and 536 serve as input ends IP₃ and IN₄, and the drain electrodes of the two PMOS transistors 533 and 536 serve as output ends ON₄ and OP₃. The source electrodes of two PMOS transistors 533 and 536 are coupled to the second current-source circuit 56. Furthermore, the input end IP₃ of the second gain circuit 53 serves positive input IP along with the input end IP₁ of the first gain circuit 43, the input end IN₄ of the second gain circuit 53 serves negative input IN along with the input end IN₂ of the first gain circuit 43, the output end OP₃ of the second gain circuit 53 serves positive output OP along with the output end OP₁ of the first gain circuit 43, the output end ON₄ of the second gain circuit 53 serves negative output ON along with the output end ON₂ of the first gain circuit 43.

The second current-source circuit 56 includes a third PMOS transistor 565. The drain electrode of the third PMOS transistor 565 is coupled to the source electrodes of the two PMOS transistors 533 and 536. The source electrode of the third PMOS transistor 565 is coupled to a voltage source V_{CC} and the gate electrode of the third PMOS transistor 565 is coupled to a second control voltage V_{B}. By way of the control voltage V_{B}, the current output from the drain electrode of the third PMOS transistor 565 to the two PMOS transistors 533 and 536 is controlled. The second load circuit 59 is also a cross-coupled load circuit, which includes a fourth NMOS transistor 593 and a fifth NMOS transistor 596. The drain electrodes of the two NMOS 593 and 596 are respectively coupled to the output ends ON₄ and OP₃, and in addition, coupled to the gate electrodes of each other. Both the source electrodes of the two NMOS transistors 593 and 596 are further coupled to ground.

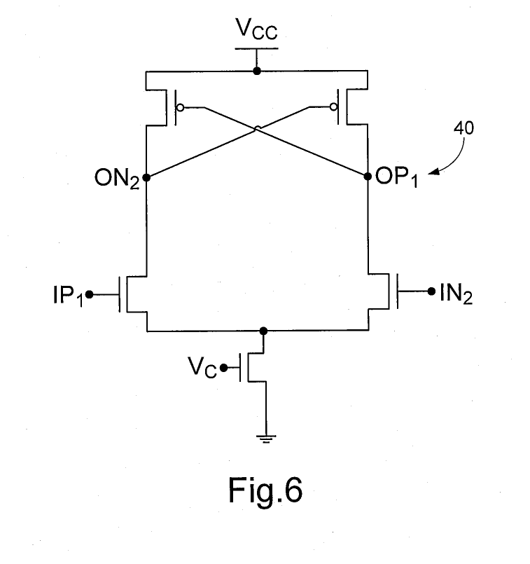

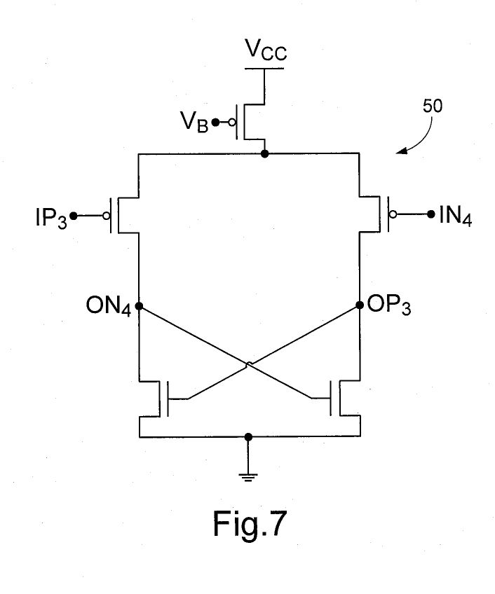

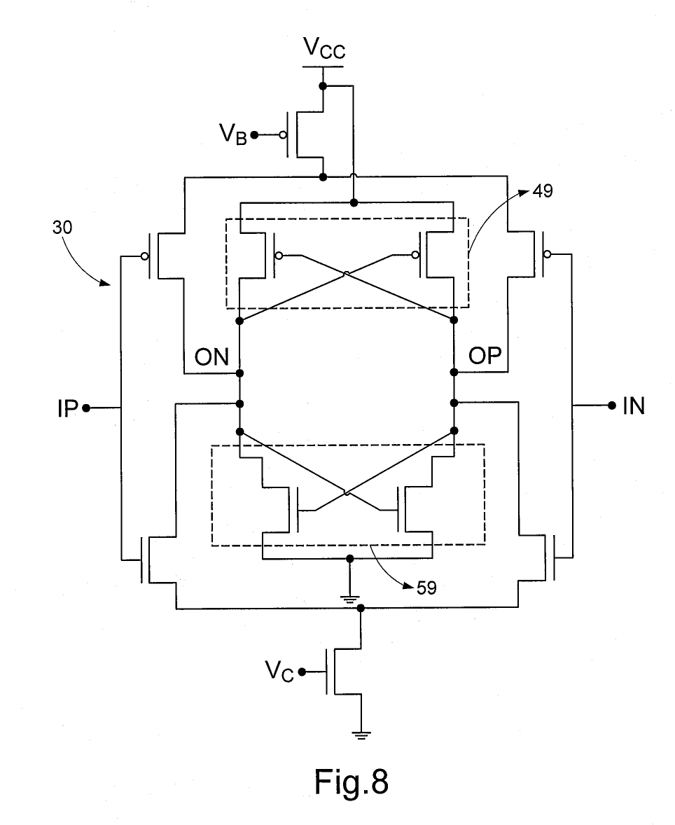

As mentioned above, the delay unit according to the present invention has a complementary architecture and includes an NMOS voltage control oscillating circuit and a PMOS voltage control oscillating circuit. The present delay unit has equivalent number of NMOS and PMOS transistors, and generates a clock signal with improved duty cycle and high frequency compared to that has unequal number of NMOS and PMOS transistors. An example of the present delay circuit and two comparative examples and their performance are illustrated hereinafter with reference to FIGS. 6˜9 for realizing the advantageous features of the present delay circuit. The circuit diagram shown in FIG. 6 is a delay unit implemented with an NMOS voltage control oscillating circuit 40 in FIG. 5, the circuit diagram shown in FIG. 7 is a delay unit implemented with a PMOS voltage control oscillating circuit 50 in FIG. 5, and the circuit diagram shown in FIG. 8 is a delay unit implemented with a complementary voltage control oscillating circuit 30 in FIG. 5. Furthermore, as shown in FIG. 8, the NMOS voltage control oscillating circuit 40 and the PMOS voltage control oscillating circuit 50 are properly integrated to be the complementary voltage control oscillating circuit 30 so as to reduce the layout area.

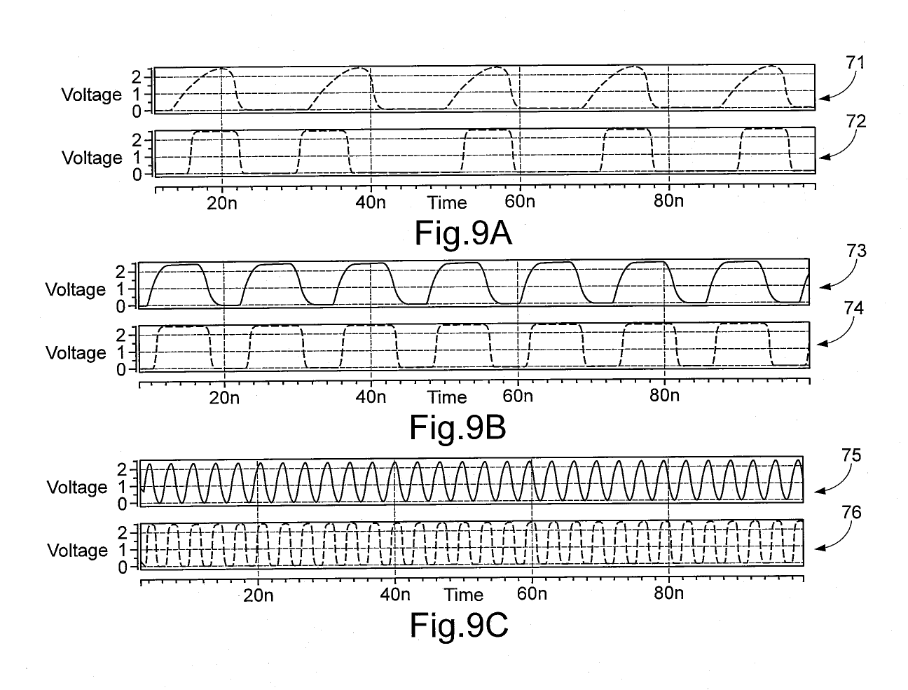

FIGS. 9A˜9C are waveform diagrams showing the clock signals 71, 73 and 75 generated by three four-stage ring oscillators implemented with the delay units of FIGS. 6, 7 and 8, respectively. The conditions applied to the three oscillators are the same. That is, the NMOS transistors and PMOS transistors used in the delay units are identical, and the control voltages applied thereto are also the same. The clock signals 72, 74 and 76 resulting from the rectification of clock signals 71, 73 and 75 through a buffer (not shown) are simultaneously shown for comparison.

It is apparent from FIGS. 9A, 9B and 9C that while the duty cycles of the clock signals 72 and 74 are away from 50%, the duty cycle of the clock signal 76 is almost ideally 50%. Furthermore, according to the ratio of generated frequency to consumed current of the three oscillators, which are 54.3 MHZ/528 μA, 78.6 MHZ/890 μA, and 306 MHZ/1.827 μA, respectively, it is clear that the oscillator implemented with the delay unit of FIG. 8 according to the present invention is capable of generating a clock signal with highest frequency per unit of current consumption.

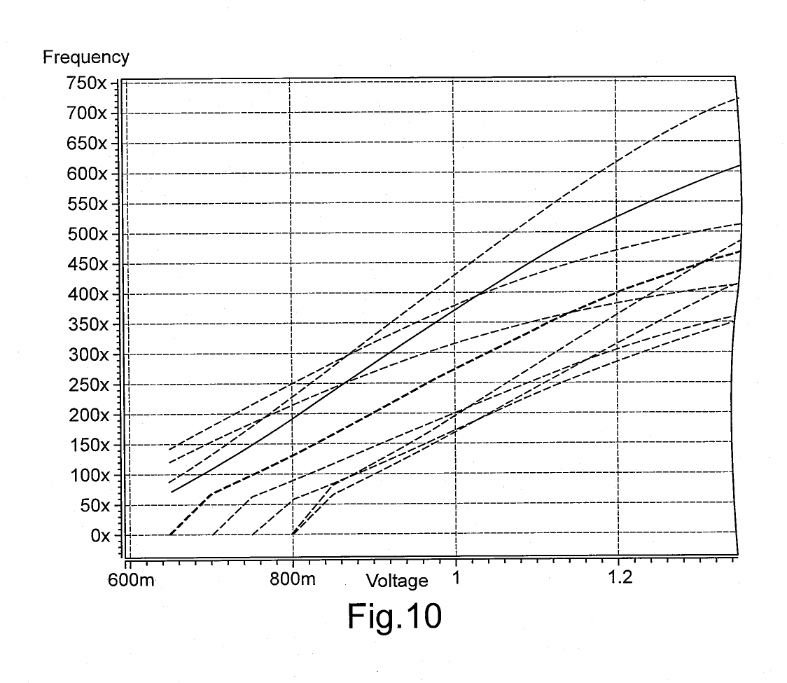

The present invention is also advantageous in enhancing operational frequency and operable range due to the less sensitive and stable features of a complementary delay unit. The present invention is further advantageous in improved gain due to the parallel connection configuration of the NMOS oscillating circuit and the PMOS oscillating circuit. FIG. 10 is a frequency vs. voltage plot of the voltage control oscillator according to the present invention, obtained as a result of corner simulation. The voltage control oscillator includes a series of delay units of FIG. 8. The curves shown in FIG. 10 represent different corners, e.g. TT (Typical NMOS/Typical PMOS), SS (Slow NMOS/Slow PMOS), SF (Slow NMOS/Fast PMOS), FS (Fast NMOS/Slow PMOS) and FF (Fast NMOS/Fast PMOS), etc. When the frequency is 350 MHZ, the oscillator of the invention only needs a V_{C} range of 0.4 V to cover nine different corners, while it needs a V_{C} range of 1V for a conventional oscillator to have the same performance. Once a high-end process is performed, the performance of the present delay unit would be even prominent.

In the embodiment of delay unit shown in FIG. 5, the first gain circuit 43, the first current-source circuit 46 and the first load circuit 49 of the NMOS voltage control oscillating circuit 40 are all respectively complementary to the second gain circuit 53, the second current-source circuit 56 and the second load circuit 59 of the PMOS voltage control oscillating circuit 50. However, only one or two complementary pairs of the gain circuit, current-source circuit and load circuit are still beneficial to the oscillating performance. Although a ring oscillator is exemplified to show the implementation and advantages of the present delay unit, the present delay unit can be applied to other types of oscillator such as an inductor-capacitor oscillator as well.

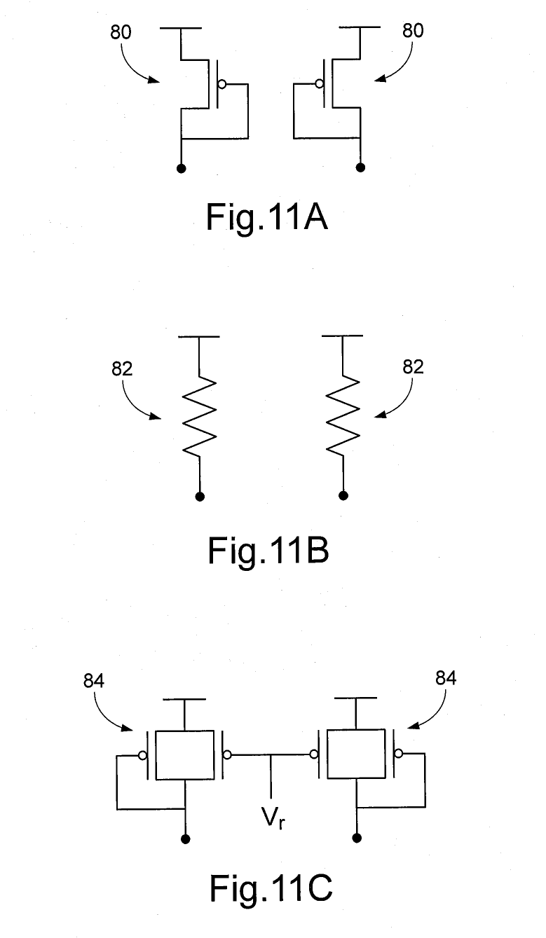

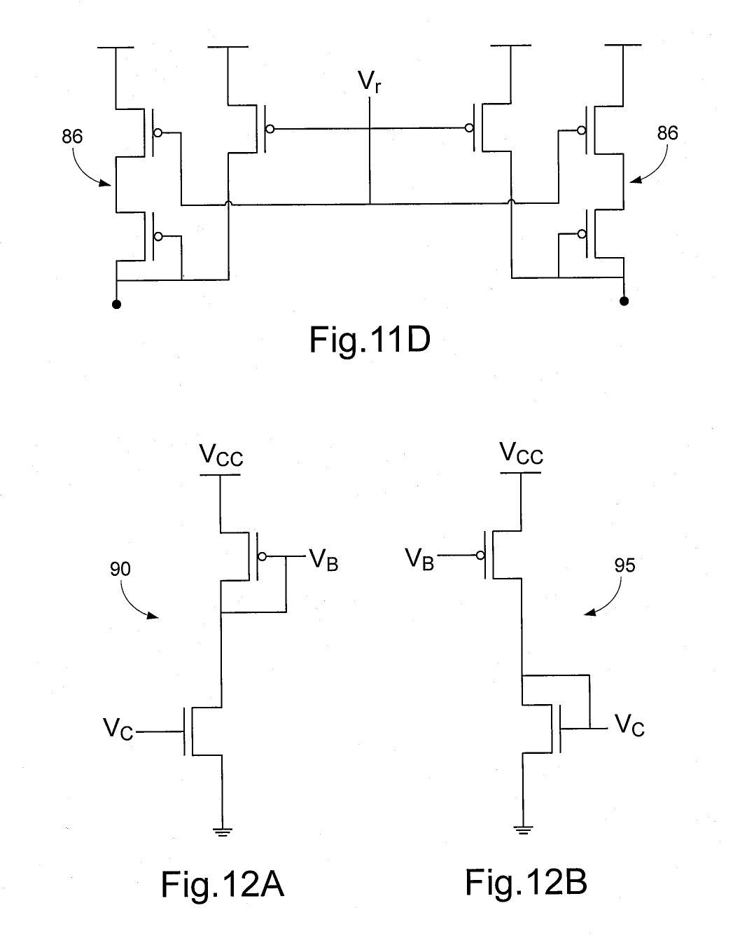

Furthermore, although a cross-coupled load circuit is used as a load circuit in the embodiment of FIG. 5, it can be replaced by other types of loading circuit, e.g. diode load circuit 80 of FIG. 11A, resistor load circuit 82 of FIG. 11B, symmetric load circuit 84 of FIG. 11C (see IEEE JOURNAL OF SOLID-STATE CIRCUITS, VOL. 31, NO. 11, NOVEMBER 1996), or voltage control resistor load circuit 86 of FIG. 11D (see IEEE JOURNAL OF SOLID-STATE CIRCUITS, VOL. 36, NO. 3, MARCH 2001). It is to be noted that the complementary feature of the delay unit should be taken into consideration upon replacement of elements. For example, if the load circuits 49 and 59 of FIG. 5 are the only complementary parts in an embodiment of the delay unit, the PMOS-based load circuit 80, 84 or 86 can only replace for the first load circuit 49, and the second load circuit 59 needs NMOS-based replacement. To reduce the phase noise, it is preferred to minimize the number of the components of the delay unit.

The delay unit 30 of the invention can be applied to both single ended type and differential type voltage control oscillators without any modification of the delay unit circuit itself. When applied to a single ended type voltage control oscillator, it is only needed to add a mirror circuit 90 as shown in FIG. 12A. In this application, the single control voltage received by the single ended type voltage control oscillator is used as the first control voltage V_{C} illustrated in FIG. 5. Then, the second control voltage V_{B} is generated in response to the first control voltage V_{C} by way of the mirror effect of the mirror circuit 90. Alternatively, the single control voltage received by the single ended type voltage control oscillator can be used as the second control voltage V_{B}, and the first control voltage V_{C} can be obtained in response to the second control voltage V_{B} by way of the mirror effect of a mirror circuit 95, as shown in FIG. 12B. In the case that the delay unit 30 of the invention is applied to a differential type oscillator, the two differential voltages inputted to the differential type oscillator serve as the first control voltage V_{C} (positive end) and the second control voltage V_{B} (negative end), respectively, to be transmitted to the first current-source circuit 46 and the second current-source circuit 56.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A delay unit for use in a voltage control oscillator, comprising:
a first voltage control oscillating circuit, comprising:
a first gain circuit having a first input end, a second input end, a first output end and a second output end;
a first current-source circuit coupled to the first gain circuit; and
a first load circuit coupled to the first output end and the second output end; and
a second voltage control oscillator circuit, comprising:
a second gain circuit having a third input end, a fourth input end, a third output end and a fourth output end, the third input end, the fourth input end, the third output end and the fourth output end being coupled to the first input end, the second input end, the first output end and the second output end, respectively;
a second current-source circuit coupled to the second gain circuit; and
a second load circuit coupled to the third output end and the fourth output end;
wherein at least one pair of the first and second gain circuits, the first and second current-source circuits and the first and second load circuits are implemented with complementary integrated circuits.

2. The delay unit according to claim 1 wherein the first and second gain circuits are complementary to each other,
the first gain circuit comprises:
a first NMOS transistor having a gate electrode and a drain electrode serving as the first input end and the second output end, respectively, and a source electrode coupled to the first current-source circuit; and
a second NMOS transistor having a gate electrode and a drain electrode serving as the second input end and the first output end, respectively, and a source electrode coupled to the first current-source circuit; and
the second gain circuit comprises:
a first PMOS transistor having a gate electrode and a drain electrode serving as the third input end and the fourth output end, respectively, and a source electrode coupled to the second current-source circuit; and
a second PMOS transistor having a gate electrode and a drain electrode serving as the fourth input end and the third output end, respectively, and a source electrode coupled to the second current-source circuit.

3. The delay unit according to claim 1 wherein the first and second current-source circuits are complementary to each other,
the first current-source circuit comprises:
a third NMOS transistor having a gate electrode coupled to a first control voltage, a source electrode coupled to ground, and a drain electrode coupled to the first gain circuit; and
the second current-source circuit comprises:
a third PMOS transistor having a gate electrode receiving a second control voltage, a source electrode coupled to a voltage source, and a drain electrode coupled to the second gain circuit.

4. The delay unit according to claim 1 wherein the first and second load circuits are selected from diode load circuits, resistor load circuits, symmetric load circuits, voltage control resistor load circuits or cross-coupled circuits.

5. The delay unit according to claim 1 wherein the first and second load circuits are complementary to each other,
the first load circuit comprises:
a fourth PMOS transistor having a drain electrode coupled to the second output end and a source electrode coupled to a voltage source; and
a fifth PMOS transistor having a drain electrode coupled to the first output end and a gate electrode of the fourth PMOS transistor, a source electrode coupled to the voltage source, and a gate electrode coupled to the drain electrode of the fourth PMOS transistor; and
the second load circuit comprises:
a fourth NMOS transistor having a drain electrode coupled to the fourth output end and a source electrode coupled to ground; and
a fifth NMOS transistor having a drain electrode coupled to the third output end and a gate electrode of the fourth NMOS transistor, a source electrode coupled to ground, and a gate electrode coupled to the drain electrode of the fourth NMOS transistor.

6. A delay unit for use in a voltage control oscillator, comprising:
a NMOS voltage control oscillating circuit having a first input end, a second input end, a first output end and a second output end; and
a PMOS voltage control oscillating circuit having a third input end coupled to the first input end, a fourth input end coupled to the second input end, a third output end coupled to the first output end, and a fourth output end coupled to the second output end.

7. The delay unit according to claim 6 wherein the NMOS voltage control oscillating circuit comprises:
a first gain circuit coupled to the first input end, the second input end, the first output end and the second output end;
a first current-source circuit coupled to the first gain circuit; and
a first load circuit coupled to the first output end and the second output end; and
a PMOS voltage control oscillator circuit, comprising:
a second gain circuit coupled to the third input end, the fourth input end, the third output end and the fourth output end, the third input end, the fourth input end, the third output end and the fourth output end being coupled to the first input end, the second input end, the first output end and the second output end, respectively;
a second current-source circuit coupled to the second gain circuit; and
a second load circuit coupled to the third output end and the fourth output end;
wherein at least one pair of the first and second gain circuits, the first and second current-source circuits and the first and second load circuits are implemented with complementary integrated circuits.

8. The delay unit according to claim 6 wherein the first and second gain circuits are complementary to each other,
the first gain circuit comprises:
a first NMOS transistor having a gate electrode and a drain electrode serving as the first input end and the second output end, respectively, and a source electrode coupled to the first current-source circuit; and
a second NMOS transistor having a gate electrode and a drain electrode serving as the second input end and the first output end, respectively, and a source electrode coupled to the first current-source circuit; and
the second gain circuit comprises:
a first PMOS transistor having a gate electrode and a drain electrode serving as the third input end and the fourth output end, respectively, and a source electrode coupled to the second current-source circuit; and
a second PMOS transistor having a gate electrode and a drain electrode serving as the fourth input end and the third output end, respectively, and a source electrode coupled to the second current-source circuit.

9. The delay unit according to claim 6 wherein the first and second current-source circuits are complementary to each other,
the first current-source circuit comprises:
a third NMOS transistor having a gate electrode coupled to a first control voltage, a source electrode coupled to ground, and a drain electrode coupled to the first gain circuit; and
the second current-source circuit comprises:
a third PMOS transistor having a gate electrode receiving a second control voltage, a source electrode coupled to a voltage source, and a drain electrode coupled to the second gain circuit.

10. The delay unit according to claim 6 wherein the first and second load circuits are selected from diode load circuits, resistor load circuits, symmetric load circuits, voltage control resistor load circuits or cross-coupled circuits.

11. The delay unit according to claim 6 wherein the first and second load circuits are complementary to each other,
the first loading circuit comprises:
a fourth PMOS transistor having a drain electrode coupled to the second output end and a source electrode coupled to a voltage source; and
a fifth PMOS transistor having a drain electrode coupled to the first output end and a gate electrode of the fourth PMOS transistor, a source electrode coupled to the voltage source, and a gate electrode coupled to the drain electrode of the fourth PMOS transistor; and
the second loading circuit comprises:
a fourth NMOS transistor having a drain electrode coupled to the fourth output end and a source electrode coupled to ground; and
a fifth NMOS transistor having a drain electrode coupled to the third output end and a gate electrode of the fourth NMOS transistor, a source electrode coupled to ground, and a gate electrode coupled to the drain electrode of the fourth NMOS transistor.

12. A delay unit for use in a voltage control oscillator, comprising:
a first voltage control oscillating circuit; and
a second voltage control oscillating circuit coupled to the first voltage control oscillating circuit and complementary to the first voltage control oscillating circuit.

13. The delay unit according to claim 12 wherein the first voltage control oscillating circuit comprises:
a first gain circuit coupled to a first input end, a second input end, a first output end and a second output end;
a first current-source circuit coupled to the first gain circuit; and
a first load circuit coupled to the first output end and the second output end; and
a second voltage control oscillator circuit, comprising:
a second gain circuit coupled to a third input end, a fourth input end, a third output end and a fourth output end, the third input end, the fourth input end, the third output end and the fourth output end being coupled to the first input end, the second input end, the first output end and the second output end, respectively;
a second current-source circuit coupled to the second gain circuit; and
a second load circuit coupled to the third output end and the fourth output end;
wherein each pair of the first and second gain circuits, the first and second current-source circuits and the first and second load circuits are implemented with complementary integrated circuits.

14. The delay unit according to claim 12 wherein the first and second gain circuits are coupled to each other.

15. The delay unit according to claim 12 wherein the first and second load circuits are coupled to each other, and selected from cross-coupled load circuits, diode load circuits, symmetric load circuits or voltage control resistor load circuits.
